(19) United States
(12) Patent Application Publication
(10) Pub. No.: US 2010/0224911 A1
(43) Pub. Date: Sep. 9, 2010

(54) Gallium nitride high electron mobility transistor

(75) Inventors: Hideyuki Okita, Saitama (JP); Shinichi Hoshi, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/659,374

(22) Filed: Mar. 5, 2010

(30) Foreign Application Priority Data
Mar. 6, 2009 (JP) 2009-052989

(51) Int. Cl. H01L 29/778

(52) U.S. Cl. 257/194; 257/E29.246

(57) ABSTRACT

There is provided a gallium nitride high electron mobility transistor including: a channel layer that lets a carrier travel at high velocity; a carrier supply layer that generates the carrier; and a cap layer, disposed on the carrier supply layer and functioning to prevent oxidation of the carrier supply layer, to reduce gate leakage current, and to increase voltage withstand to gate voltage, wherein a thickness of the cap layer is set at a minimum as thicker than 11 nm.

### CROSS-REFERENCE TO RELATED APPLICATION

This application is based on and claims priority under 35 USC 119 from Japanese Patent Application No. 2009-052989 filed on Mar. 6, 2009, the disclosure of which is incorporated by reference herein.

### BACKGROUND

1. Technical Field

The present invention relates to a gallium nitride high electron mobility transistor (HEMT), and in particular to a gallium nitride-HEMT suppressing shifts in threshold voltages, capable of setting with a high forward voltage value, and capable of increasing the saturation output voltage.

2. Related Art

Gallium nitride-HEMT's (sometimes referred to below as GaN HEMT's) have both high breakdown voltages and high saturated electron velocities. AlGaN/GaN hetero structure HEMT's utilizing these characteristics have drawn attention as high speed devices (see, for example, Japanese Patent Application Laid-Open (JP-A) Nos. 2002-359256 and 2004-228481).

In order to clarify the purpose of the present invention, a discussion follows of the operation characteristics of conventional configuration GaN HEMT's. First, a configuration of a GaN HEMT of conventional configuration is explained, with reference to FIG. 1.

FIG. 1 is a schematic cross-section explaning a configuration of a GaN HEMT. When forming an HEMT using a SiC crystal substrate as a crystal substrate 10, an AlN layer is employed as a buffer layer 12 and a GaN layer is employed as a channel layer 14. Furthermore, a non-doped or Si-doped i-AlGaN layer, having an Al composition ratio of 15 to 30% and thickness of 10 nm to 30 nm, is employed as a carrier supply layer 16, and a non-doped i-GaN layer, of thickness 0 nm to 10 nm, is employed as a cap layer 18. In practice in a GaN HEMT, a source electrode 22, a drain electrode 26, and a gate electrode 24 are additionally formed on the cap layer 18, with a SiN passivation film 20 interposed therebetween. During operation of the GaN HEMT of FIG. 1, a two dimensional electron gas channel 28 is formed in the vicinity of the boundary between the channel layer 14 and the carrier supply layer 16, at the position in the channel layer 14 shown by the intermittent line.

Explanation follows regarding the operation characteristics of a conventional GaN HEMT, with reference to FIG. 2 and FIG. 3. FIG. 2 is a graph showing I_{ds}-V_{ds} characteristics, giving the relationship of the drain current I_{ds} against the drain voltage V_{ds}, and FIG. 3 is a graph showing I_{gs}-V_{gs} characteristics, giving the relationship of the gate current I_{gs} against the gate voltage V_{gs}.

In FIG. 2, the value of the drain voltage V_{ds} is shown with a scale of units of V on the horizontal axis, and the value of the drain current I_{ds} is shown with a scale of units of mA/mm on the vertical axis. FIG. 2 shows cases where the gate voltage V_{gs} is V_{gs}=−1V, V_{gs}=0V, V_{gs}=+1V, and V_{gs}=+2V.

In FIG. 3, the value of the gate voltage V_{gs} is shown with a scale of units of V on the horizontal axis, and the value of the gate current I_{gs} is shown with a logarithmic scale of units of mA/mm on the vertical axis. On the vertical axis of FIG. 3, for example, 1.E+01 (mA/mm) indicates 10¹ (mA/mm), namely 10 (mA/mm). In a similar manner, 1.E+00 (mA/mm) and 1.E−01 (mA/mm) indicate 10⁰ (mA/mm), namely 1 (mA/mm), and 10⁻¹ (mA/mm), namely 0.1 (mA/mm), and so forth.

In a conventional GaN HEMT, the value of the forward voltage V_{f} is about 0.8V. The forward voltage V_{f} is defined, in the I_{gs}-V_{gs} characteristics, as the value of the gate voltage V_{gs} applied as the gate voltage that is attained when the value of the gate current I_{gs} in the forward direction is made to be 1 mA/mm. In FIG. 3, the value of the forward voltage V_{f} of the conventional GaN HEMT is about 0.8V, as shown by the right-facing arrow.

Therefore, it is difficult to set the gate voltage value any higher than this value, since on the I_{ds}-V_{ds} characteristics curve shown in FIG. 2, when the gate voltage V_{gs} is set to +2V or higher, a large current flows in the forward direction through the gate, leading to element breakdown. Namely, in a conventional GaN HEMT, since the forward voltage V_{f} is low, about 0.8V, it is difficult to set the gate voltage V_{gs} at +2V or higher.

However, if the forward voltage V_{f} could be made higher, it would also be possible to increase the drain current I_{ds}. Explanation follows with reference to FIG. 4. FIG. 4, similarly to FIG. 2, is a graph showing I_{ds}-V_{ds} characteristics, giving the relationship of the drain current I_{ds} against the drain voltage V_{ds}, and FIG. 4 shows cases where the gate voltage V_{gs} is V_{gs}=−1V, V_{gs}=0V, V_{gs}=+1V, V_{gs}=+2V, V_{gs}=+3V, V_{gs}+4V. As shown in FIG. 4, it can be seen that from the saturation current value at V_{gs}=+4V being about 800 mA/mm, by obtaining a larger amplitude change in the gate voltage V_{gs}, it is possible to increase the drain current I_{ds}.

From the standpoint of operation of the GaN HEMT as a power device, if the saturated output power is denoted Pₛₐₜ, then Pₛₐₜ approximates to the following Equation (1).

Pₛₐₜ≈(ΔV_{ds}×ΔI_{ds})/8 (1)

Wherein ΔV_{ds} is the amplitude of change in drain voltage and ΔI_{ds} is the amplitude of change in the drain current. The constant ⅛ appearing in Equation (1) is for computation of the saturation power output Pₛₐₜ utilizing effective values of the drain voltage and drain current, respectively. Namely, since effective values of the drain voltage and the drain current are each respectively 1/(2×2^{1/2}) of the alternating current amplitude values, the constant ⅛ appears as the product of {1/(2×2^{1/2})}×{1/(2×2^{1/2})}=⅛.

Assuming class-A operation in a high frequency band for the GaN HEMT, for example, if the reference voltage value is 50V, then the value of ΔV_{ds} is 100V, twice that of the reference voltage value 50V. The value of the ΔI_{ds} is equivalent to I_{ds-max}, this being the maximum value of the drain current I_{ds}. As explained above, the drain current I_{ds} is limited by the forward voltage V_{f}, and the higher the forward voltage V_{f}, enables an increase in the I_{ds-max}, this being the maximum value of the drain current I_{ds}, and hence an increase in the saturation power output Pₛₐₜ is also enabled. By being able to increase the saturation power output Pₛₐₜ, the current density of the drain current can be increased, and as a result this contributes to miniaturization of the device.

By employing a Metal-Insulator-Semiconductor (MIS) structure using a SiN film (see, for example, JP-A No. 6-334176), the absolute value of the forward voltage V_{f} can be made greater, however, in techniques using a SiN film, the absolute value of the threshold voltage Vₜₕ of negative potential also becomes greater, with the problem that the mutual conductance gₘ is reduced. When the mutual conductance gₘ is reduced, then this has an effect on the size of the cut-off frequency f_{T}, one of the high-frequency characteristics of the element.

The threshold voltage Vₜₕ here refers to the minimum gate voltage value at which current starts flowing between the source and the drain (in the case of a normally-off HEMT), or the minimum gate voltage value at which current stops flowing between the source and the drain (in the case of a normally-on HEMT).

The cut-off frequency f_{T} is defined as the frequency value when the amplification ratio becomes 1, namely the minimum frequency at which an amplification effect is not obtained at this frequency or above, and is given by the following Equation (2).

f_{T}=gₘ/(2πC_{gs}) (2)

C_{gs} here is a value of the parasitic capacitance between the gate and the source induced by the gate electrode structure (inter gate-source parasitic capacitance). In Equation (2), it can be seen that when the mutual conductance gₘ is decreased, the cut-off frequency f_{T} also decreases.

As described above, it can be seen that by employing the conventional technique of an MIS structure using an SiN film as described above, although a shift in the threshold voltage Vₜₕ is suppressed, it is difficult to increase the absolute vale of the forward voltage V_{f}.

In order to solve the issue described above, it has been discovered, as a result of research by the inventors of this application, that by making the thickness of the cap layer 18 thicker than 11 nm, the forward voltage V_{f} can be increased linearly, with hardly any change in the threshold voltage Vₜₕ. It has been found that by utilizing this characteristic, the I_{ds-max}, this being the maximum value of the drain current I_{ds}, can be increased without changing the threshold voltage Vₜₕ, enabling the saturation power output Pₛₐₜ to be increased.

### SUMMARY

Consequently, the present invention is made in consideration of the above circumstances and an objective thereof is to provide a GaN HEMT that suppresses shift in the threshold voltage Vₜₕ, is capable of setting with a large positive value for the forward voltage V_{f}, and is capable of increasing the saturation power output Pₛₐₜ.

In consideration of the above circumstances, the present invention provides a GaN HEMT of the following configuration, in accordance with the spirit of the present invention.

The GaN-HEMT of the present invention is a GaN-HEMT including: a channel layer that lets a carrier transit at high velocity; a carrier supply layer that generates the carrier; and a cap layer, disposed on the carrier supply layer and functioning to prevent oxidation of the carrier supply layer, to reduce gate leakage current, and to increase voltage withstand to gate voltage, wherein the thickness of the cap layer is set at a minimum as thicker than 11 nm.

In the GaN-HEMT of the present invention, preferably the thickness of the carrier supply layer is set in a range enabling the threshold voltage to adopt a positive value, in order to realize a GaN-HEMT of normally-off operation.

Furthermore, the cap layer is preferably an AlₓIn_{y}Ga_{1-x-y}N crystal layer, doped with Si in a range from 0 to 5×10¹⁸ cm⁻³.

Furthermore, the cap layer is an AlₓIn_{y}Ga_{1-x-y}N crystal layer where the values of x and y, giving composition ratios, are set in a range that satisfies 0≦x<0.1, and 0≦y<0.1.

Furthermore, the carrier supply layer is preferably formed from AlₓGa₁₋ₓN crystal, with the thickness of the carrier supply layer set at values of 15 nm or less, 10 nm or less, and 4 nm or less for values of the composition ratio x of the AlₓGa₁₋ₓN set at 0.15, 0.20 and 0.25, respectively.

According to the GaN-HEMT of the spirit of the invention as described above, corresponding to an increase in the thickness of the cap layer, the forward voltage V_{f} increases with hardly any effect on the threshold voltage Vₜₕ. Consequently, by making the thickness of the cap layer 18 thicker than 11 nm, realization is enabled of a GaN-HEMT in which shift in the threshold voltage Vₜₕ can be suppressed as far as possible, the forward voltage value is capable of being set high, and the saturation power output Pₛₐₜ is capable of being increased.

Furthermore, in the GaN-HEMT, by making the thickness of the cap layer thicker than 11 nm, and also setting the thickness of the carrier supply layer so the threshold voltage can be a positive value, realization is enabled of a normally-off operating GaN-HEMT in which the forward voltage value can be made greater, and the saturation power output Pₛₐₜ can be increased.

Furthermore, by making the Si doping amount to the cap layer 0 to 5⁻×10¹⁸ cm⁻³, a reduction in current collapse effect is expected.

Furthermore, when the composition ratios x and y of the AlₓIn_{y}Ga_{1-x-y}N forming the cap layer are set to satisfy 0≦x<0.1, and 0≦y<0.1, respectively, large shifts in the threshold voltage Vₜₕ can be suppressed.

### BRIEF DESCRIPTION OF THE DRAWINGS

Exemplary embodiments of the present invention will be described in detail based on the following figures, wherein:

FIG. 1 is a schematic cross-section explaining a configuration of a GaN HEMT;

FIG. 2 is a graph showing I_{ds}-V_{ds} characteristics, giving the relationship of the drain current I_{ds} against the drain voltage V_{ds};

FIG. 3 is a graph showing I_{gs}-V_{gs} characteristics, giving the relationship of the gate current I_{gs} against the gate voltage V_{gs};

FIG. 4 is a graph showing I_{ds}-V_{ds} characteristics, giving the relationship of the drain current I_{ds} against the drain voltage V_{ds};

FIG. 5 is a schematic cross-section explaining a configuration of a first GaN HEMT of the present invention;

FIG. 6 is a graph showing the dependency of the I_{gs}-V_{gs} characteristics, giving the relationship of the gate current I_{gs} against the gate voltage V_{gs}, on the thickness of a cap layer;

FIG. 7 is a graph showing the relationship between the forward voltage V_{f} and the threshold voltage Vₜₕ against the thickness of a cap layer;

FIG. 8A is a schematic cross-section explaining a fabrication process of a GaN HEMT of the present invention, and in particular a diagram showing a cross-section structure of an epitaxial growth substrate used for growing a GaN HEMT;

FIG. 8B is a schematic cross-section explaining a fabrication process of a GaN HEMT of the present invention, and in particular a diagram showing an element formed with a photoresist film;

FIG. 9A is a schematic cross-section explaining a fabrication process of a GaN HEMT of the present invention, and in particular a diagram showing an element with an element isolation layer formed by performing ion implantation;

FIG. 9B is a schematic cross-section explaining a fabrication process of a GaN HEMT of the present invention, and in particular a diagram showing an element in which a photoresist film has been reformed on a protection film;

FIG. 9C is a schematic cross-section explaining a fabrication process of a GaN HEMT of the present invention, and in particular a diagram showing an element in which a SiN film exposed at resist openings has been removed by an RIE method, and recess portions formed by dry-etching down to portions of a channel layer;

FIG. 10A is a schematic cross-section explaining a fabrication process of a GaN HEMT of the present invention, and in particular a diagram showing an element formed with a metal thin film using, for example, an electron beam vacuum deposition method or the like;

FIG. 10B is a schematic cross-section explaining a fabrication process of a GaN HEMT of the present invention, and in particular a diagram showing an element in which a metal thin film formed on a photoresist film and the photoresist film have been removed by a lift-off method;

FIG. 10C is a schematic cross-section explaining a fabrication process of a GaN HEMT of the present invention, and in particular a diagram showing an exposed state of a cap layer when locations of photoresist film, for forming gate electrodes by coating a photoresist film and using photolithography, and a portion of a protection film have been removed;

FIG. 11A is a schematic cross-section explaining a fabrication process of a GaN HEMT of the present invention, and in particular a diagram showing a state in which a metal thin film, for forming gate electrodes, has been vacuum deposited;

FIG. 11B is a schematic cross-section explaining a fabrication process of a GaN HEMT of the present invention, and in particular a diagram showing an element formed with a gate electrode using a lift-off method; and

FIG. 12 is a diagram showing a relationship of threshold voltage against thickness of a carrier supply layer when the drain voltage is 10V.

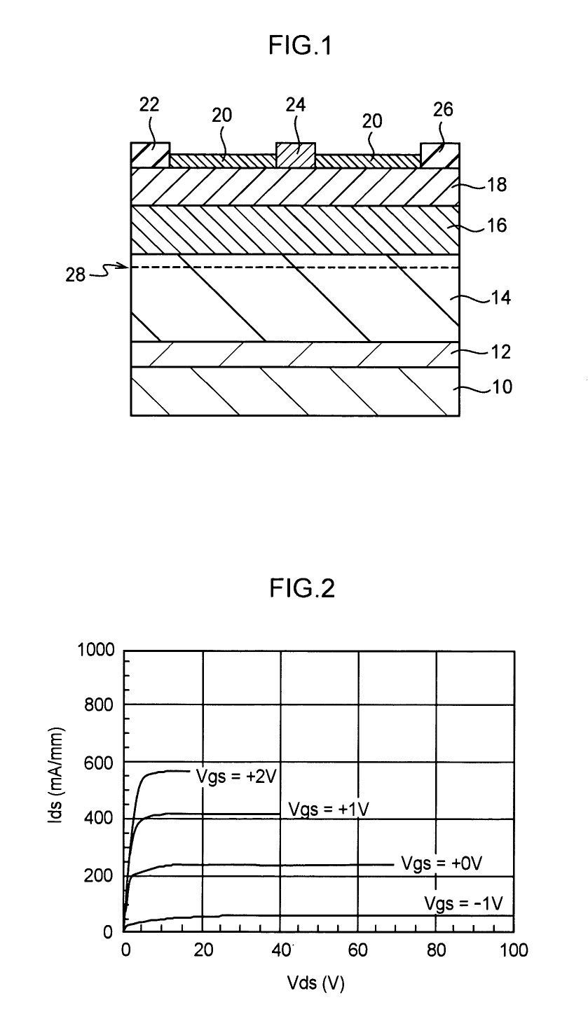

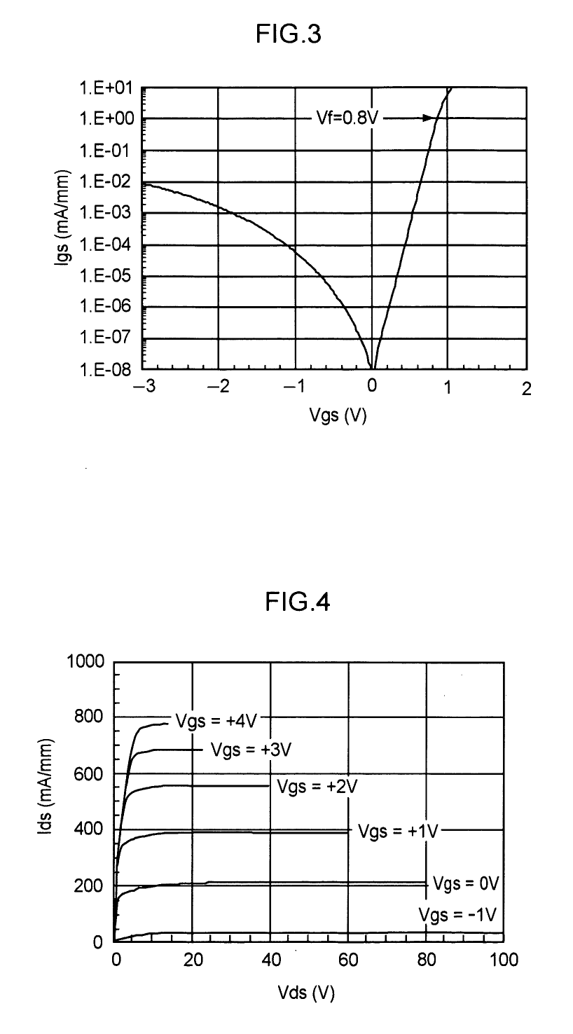

### DETAILED DESCRIPTION

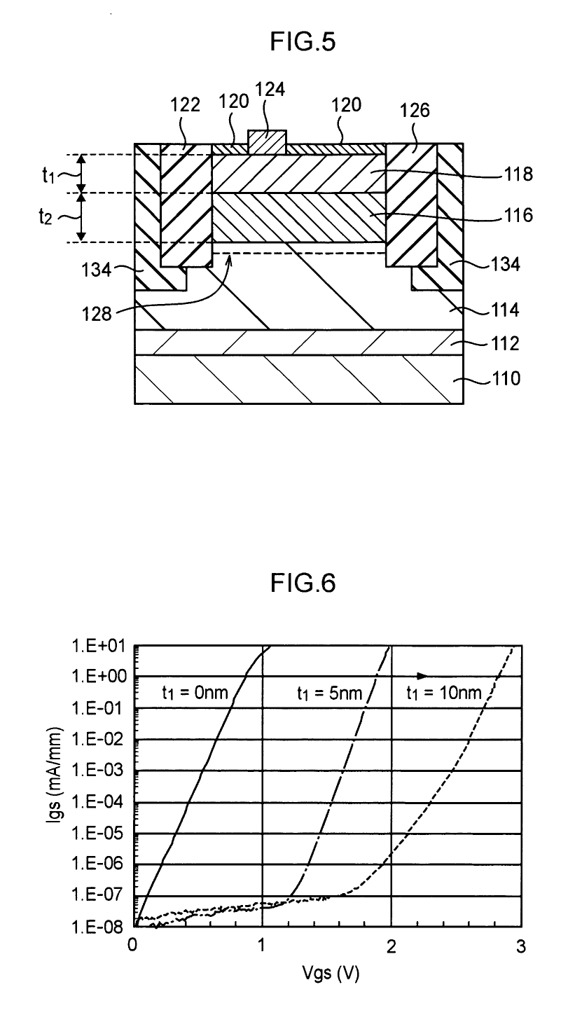

Explanation follows regarding an exemplary embodiment of the present invention, with reference to the figures. Note that FIG. 5 and FIG. 8A to FIG. 11B are no more than schematic representations at a level to enable understanding of the fundamental configuration of the HEMT of the present invention. Furthermore, while explanation is given below of preferred exemplary embodiments, the materials of each of the configuration elements, the numerical conditions, and the like, for example, are no more than preferable examples thereof. Consequently, the present invention is not limited by any of the following exemplary embodiments.

GaN HEMT of First Exemplary Embodiment

Explanation follows regarding the configuration of a GaN HEMT of a first exemplary embodiment of the present invention, with reference to FIG. 5. FIG. 5 is a schematic cross-section to accompany explanation of the configuration of the GaN HEMT of the first exemplary embodiment of the present invention.

The GaN HEMT of the first exemplary embodiment of the present invention is configured with a source electrode 122, a gate electrode 124, and a drain electrode 126 formed on an epitaxial growth substrate. The epitaxial growth substrate is a buffer layer 112, a channel layer 114, a carrier supply layer 116, and a cap layer 118 formed, in sequence, on a crystal substrate 110 by an epitaxial growth method.

An element isolation layer 134 is provided adjacent to the source electrode 122 and to the drain electrode 126, and a passivation film 120 is provided between the source electrode 122 and the gate electrode 124, and between the drain electrode 126 and the gate electrode 124. The passivation film 120 is formed from a SiN crystal film that functions as a covering film between electrodes.

The relationship between the source electrode 122 and the drain electrode 126 is a relationship determined by selection of one or other as the high potential side, namely it is a relationship in which the carrier supply side is the source electrode and the carrier destination is the drain electrode, with the electrode structures employing the same structures. In GaN-HEMT's, since the carrier is electrons, the electrode selected as the high potential side is the drain electrode. Since the carrier supply layer is a layer supplying electrodes it is sometimes referred to as an electron supply layer. The channel layer is a layer through which electrons, these being the carrier, transit with high mobility, and is also sometimes referred to as a carrier transit layer or electron transit layer.

The buffer layer 112 (AlN layer) has the role of growth nucleation when the channel layer 114 (GaN layer) is being formed by epitaxial growth. Generally it is preferable, when forming an epitaxial growth layer on a single crystal substrate, for the lattice constant of the substrate crystal and the lattice constant of the epitaxial growth crystal to be values that are close to each other. Furthermore, it is preferable for the crystal substrate face for epitaxial growth to be formed with an ordered array, without defects in the crystal lattice, however, it is difficult to expect crystal substrate faces formed by polishing to have crystal lattices with sufficiently ordered arrays.

Consequently, by forming the buffer layer 112 (AlN layer) on the surface of the crystal substrate 110 (SiC crystal substrate), favorable conditions are achieved for epitaxial growth of the channel layer 114 (GaN layer), and a state is realized in which the crystal lattice of the crystal substrate is an ordered array without defects, and with a smaller difference in size of the lattice constant.

The channel layer 114 (GaN layer) employs a GaN layer capable of letting electrons, which are the carrier, transit with high mobility.

During operation of the GaN HEMT, due to piezo polarization and spontaneous polarization in the carrier supply layer 116 (i-AlGaN layer), electrons accumulate in the upper portion of the channel layer 114 (GaN layer) formed as the layer below, and a two dimensional electron gas channel 128 is formed, capable of moving electrons at high speed. The two dimensional electron gas channel 128 is located at the position shown by the intermittent line on FIG. 5, namely forms within the channel layer 114 in the vicinity of the boundary between the channel layer 114 and the carrier supply layer 116. Note that since the carrier supply layer has the purpose of supplying carrier, the carrier supply layer may be AlIn_{z}Ga_{1-z}N, including In at a low composition (where 0≦z<0.1).

The cap layer 118 (i-GaN layer), has the effect of preventing oxidation of the carrier supply layer 116 (i-AlGN layer) that includes the readily oxidized element Al, reducing gate leakage current, and raising withstanding to gate voltage.

The crystal substrate 110 uses a SiC crystal substrate. The buffer layer 112, the channel layer 114, the carrier supply layer 116, and the cap layer 118 are formed in sequence using a Metal Organic Chemical Vapor Deposition (MOCVD) method. The buffer layer 112 is an AlN epitaxial growth layer of thickness 10 nm to 200 nm, the channel layer 114 is a GaN epitaxial growth layer, and the carrier supply layer 116 is an AlₓGa₁₋ₓN epitaxial growth layer of thickness 10 nm to 30 nm.

The carrier supply layer 116 is a non-doped AlₓGa₁₋ₓN epitaxial growth layer, with the composition ratio x set as a value in the range from 0.15 to 0.30. The cap layer 118 is a GaN epitaxial growth layer having a thickness at the minimum that thicker than 11 nm. The cap layer 118 is an Un-Intentionally Doped (UID) GaN epitaxial growth layer.

Since the cap layer 118 is a layer formed by an epitaxial crystal growth method as described above, the upper practical limit value of the thickness thereof is several tens of nm. Namely, there are few positive merits technically even if a thickness of cap layer 118 greater than this was to be secured, and the value of the upper limit of the thickness of the cap layer 118 is of the order of several tens of nm from the perspective of the requirements for industrial applicability.

A UID-GaN epitaxial growth layer is formed as an n-type conductor even without performing intentional Si doping. However, intentional Si doping may be performed, since a reduction in so-called current collapse phenomenon can be expected, where the drain current falls off during operation at high power due to the influence of electron traps. However, if the doping amount of Si is 5×10¹⁸ cm⁻³ or greater, leakage current, between the source electrode 122 and the gate electrode 124, and between the drain electrode 126 and the gate electrode 124, occurs at a level that cannot be ignored. Furthermore, since the problem of a reduction in the forward voltage V_{f} also occurs, even if the GaN epitaxial growth layer of the cap layer 118 is doped with Si, the amount is preferably 5×10¹⁸ cm⁻³ or less.

The inventors of the present invention have experimentally confirmed that when Si doping is performed at 1×10¹⁹ cm⁻³ to the cap layer 118, the leakage current between the source electrode 122 and the gate electrode 124, and between the drain electrode 126 and the gate electrode 124, is too big, and is not practically usable. Furthermore, when Si doping is performed to the cap layer 118 in a similar manner at 2×10¹⁸ cm⁻³, the leakage current value is sufficiently small, and the forward voltage V_{f} is not lowered to such an extent as to cause problems. So, from these experimentally confirmed results, the Si doping amount to the cap layer 118 is preferably 5×10¹⁸ cm⁻³ or less.

The cap layer 118 may also be an AlₓIn_{y}Ga_{1-x-y}N epitaxial growth layer (AlₓIn_{y}Ga_{1-x-y}N crystal layer), instead of the GaN epitaxial growth layer. However, as a result of experimental confirmation, when the value of the Al composition ratio x and the value of the In composition ratio y are set at 0.1 or greater, respectively, large shifts in the threshold voltage value Vₜₕ are difficult to suppress.

One of the characteristics of the GaN HEMT of the first exemplary embodiment of the present invention is that the thickness t₁ of the cap layer 118 shown in FIG. 5 is set to a thickness at the minimum of greater than 11 nm.

Explanation follows, with reference to FIG. 6, of the results of experimentation regarding how the I_{gs}-V_{gs} characteristics, giving the relationship of the gate current I_{gs} against the gate voltage V_{gs}, change according to changes in the thickness t₁ of the cap layer 118. FIG. 6 is a graph showing the I_{gs}-V_{gs}, characteristics, giving the relationship of the gate current I_{gs} against the gate voltage V_{gs}, for when thickness t₁ of the cap layer 118 is 0 nm, 5 nm, and 10 nm, respectively. In FIG. 6, the gate voltage V_{gs} is shown with a scale of units of V on the horizontal axis, and the gate current I_{gs} is shown with a logarithmic scale of units of mA/mm on the vertical axis. On the vertical axis of FIG. 6, for example, 1.E+01 (mA/mm) indicates 10¹ (mA/mm), namely 10 (mA/mm). In a similar manner, 1.E+00 (mA/mm) and 1.E-01 (mA/mm) indicate 10⁰ (mA/mm), namely 1 (mA/mm), and 10⁻¹ (mA/mm), namely 0.1 (mA/mm), respectively, and so forth.

In the measurements of the I_{gs}-V_{gs} characteristics shown in FIG. 6, a UID-GaN epitaxial growth layer is employed as the cap layer 118. As shown in FIG. 6, it can be seen that, corresponding to an increase in the thickness t₁ of the cap layer 118, the I_{gs}-V_{gs} characteristic curve, giving the gate current I_{gs} of the forward direction, shifts to the high voltage side of the gate voltage V_{gs}. Namely, as the thickness t₁ of the cap layer 118 gets thicker, an increase in the gate current I_{gs} becomes more difficult for the rise in gate voltage V_{gs}.

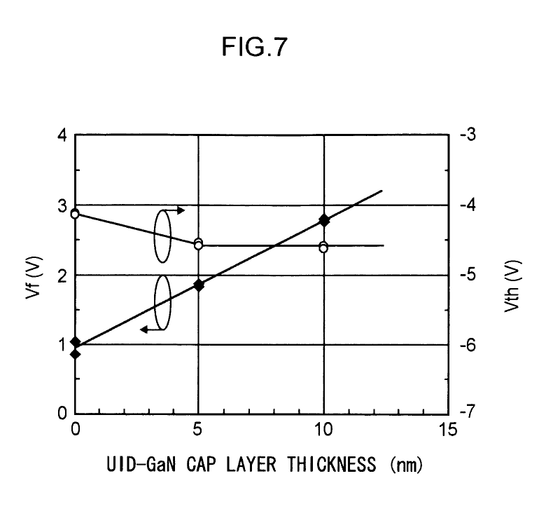

Explanation follows of the experimental results regarding the relationship between the forward voltage V_{f} and the threshold voltage Vₜₕ, with reference to FIG. 7. FIG. 7 is a graph showing the relationship between the forward voltage V_{f} and the threshold voltage Vₜₕ against the thickness of the cap layer. In FIG. 7, the thickness t₁ of the cap layer 118 is shown on a scale of units of nm on the horizontal axis, the vertical axis on the left hand side shows, with a scale of units of V, the values of the forward voltage V_{f} when the gate current I_{gs} in the forward direction achieves a value equivalent to 1 mA/mm, and the vertical axis on the right hand side shows, with a scale of units of V, the values of the threshold voltage Vₜₕ when the gate current I_{gs} in the forward direction achieves a value equivalent to 1 mA/mm. In FIG. 7, the forward voltage V_{f} is shown by black diamonds, and the threshold voltage Vₜₕ is shown by white circles.

It can be seen from FIG. 7 that as the thickness of the thickness t₁ of the cap layer 118 goes from 0 nm, to 5 nm, to 10 nm, the forward voltage V_{f} increases linearly from 0.9V to 2.8V. Furthermore, while the threshold voltage Vₜₕ decreases from −4.2V to −4.6V, the size of the forward voltage V_{f} hardly changes between when the thickness t₁ of the cap layer 118 is 5 nm and when it is 10 nm. Namely, as the thickness t₁ of the cap layer 118 goes from 0 nm, to 5 nm, to 10 nm, it can be seen that the forward voltage V_{f} increases, but the threshold voltage Vₜₕ hardly changes.

The forward voltage V_{f} is preferably as high as possible in applications of HEMT, and in particular, when operating with a threshold voltage Vₜₕ of positive value, when designing a HEMT of normally-off operation, it is preferably if a threshold voltage Vₜₕ of 1.5V or greater can be secured. Also, in order to also secure a sufficiently large drain current I_{ds}, a large difference between the forward voltage V_{f} and the threshold voltage Vₜₕ is preferable, and it is preferable if a forward voltage V_{f} at +3V or greater can be secured. Therefore, as shown in FIG. 7, the thickness t₁ of the cap layer 118 needs to be 11 nm or greater. Furthermore, when the cap layer 118 is Si doped, the thickness t₁ of the cap layer 118 needs to be even thicker, in comparison to non-doped cases.

Fabrication Method of GaN HEMT of First Exemplary Embodiment

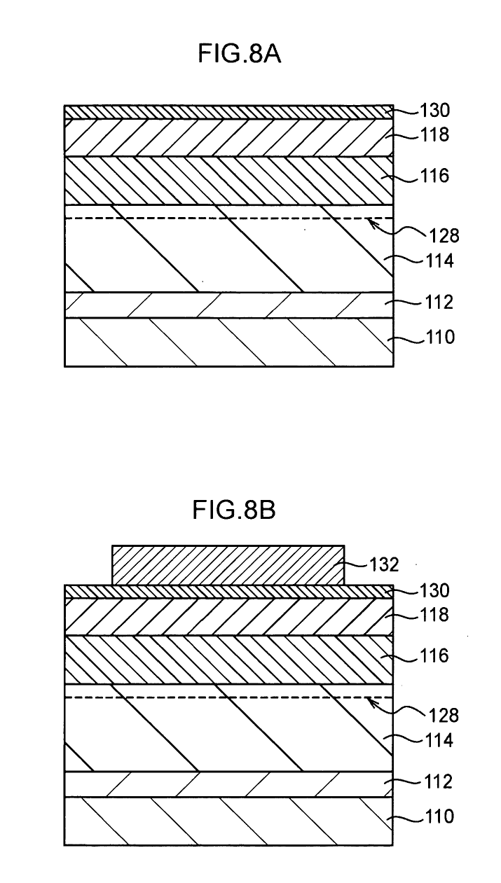

Explanation follows regarding a fabrication method of the GaN HEMT of the first exemplary embodiment of the present invention, with reference to FIG. 8A to FIG. 11B. FIG. 8A to FIG. 11B are schematic cross-sections to accompany explanation of a fabrication method of the GaN HEMT of the first exemplary embodiment of the present invention. A GaN HEMT of a second exemplary embodiment of the present invention, described below, only differs in configuration in the film thickness and the composition of the epitaxial growth layer, and since there is no difference in fabrication method between the two GaN HEMT's a combined explanation follows for the fabrication method of the GaN HEMT's of the first and the second exemplary embodiments of the present invention, with reference to FIG. 8A to FIG. 11B.

FIG. 8A is a diagram showing a cross-section structure of an epitaxial growth substrate used for forming the GaN HEMT. The GaN HEMT, as shown in FIG. 8A, is formed from an epitaxial growth substrate, of the buffer layer 112, the channel layer 114, the carrier supply layer 116, and the cap layer 118 formed, in sequence by an epitaxial growth method, on the crystal substrate 110. A protection film 130 is formed on the epitaxial growth substrate, at a thickness of 50 nm to 200 nm, using, for example, a plasma CVD (also sometimes referred to as Plasma-Enhanced Chemical Vapor. Deposition (PECVD)) method, a thermal Chemical Vapor Deposition (CVD) method, or the like.

The protection film 130 is an insulating film that becomes the passivation film (inter-electrode covering film) 120 shown in FIG. 5 when the GaN HEMT has been completed. A SiN film, a SiO₂ film or an SiON film is employed for the protection film 130. The following explanation is made on the basis that a SiN film is used as the protection film 130.

FIG. 8B is a diagram showing an element formed with a photoresist film 132, for use when forming the element isolation layer 134 with an Ion Implantation method, as described below. The photoresist film 132 is of a photoresist material and thickness suitably selected so as to have characteristics that do not let ions pass through in the ion implantation method, and the photoresist film 132 is formable by normal photolithography techniques. A positive-working resist material is preferably selected for forming the photoresist film 132.

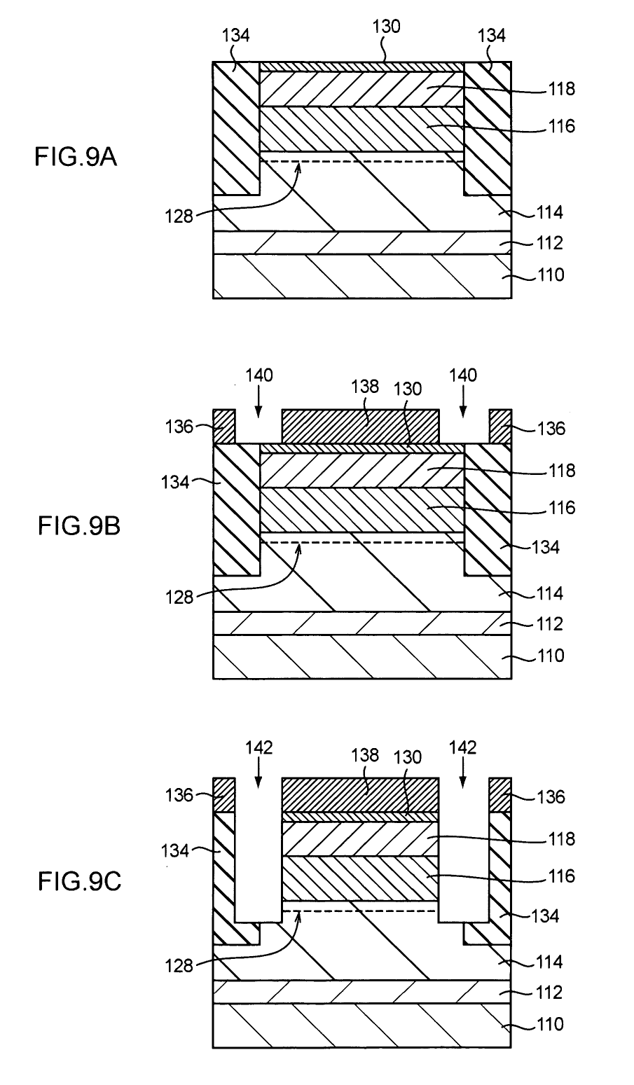

FIG. 9A is a diagram showing an element, formed with the element isolation layer 134 by performing ion implantation, with argon ions or nitrogen ions as the ion species. The photoresist film 132, formed to prevent implantation of the ion species, is then removed.

FIG. 9B is a diagram showing an element in which a photoresist film has been reformed on the protection film 130, the photoresist film has been removed from locations where the source electrode 122 and the drain electrode 126, described below, are due to be formed, and resist openings 140 are formed using normal photolithography techniques. By providing the resist openings 140, the photoresist film is separated, and a photoresist film 138 and a photoresist film 136 are formed. A negative working resist material is preferably selected as the resist material for forming the photoresist film 136 and 138.

FIG. 9C is a diagram showing an element in which the protection film 130, which is a SiN film, exposed at the resist openings 140 has been removed by a Reactive Ion Etching (RIE) method employing, for example, SF₆ gas or the like, and subsequently recess portions 142 have been formed by dry-etching down to portions of the channel layer 114 using an RIE method employing, for example, BCl₃ gas or the like.

Since the cap layer 118 formed from GaN crystal has an extremely high resistance, even if both the source electrode and the drain electrode were to be formed on the cap layer 118, electrodes arising would have non-ohmic characteristics, with extremely high contact resistance. Consequently, the cap layer 118 and the carrier supply layer 116 are preferably completely removed at locations where the source electrode and the drain electrode are to be formed, and the recess portions 142 formed by dry etching down to locations where portions of the channel layer 114 are present. Note that contact is made when the electrodes are formed on the cap surface, even though there is a high resistance. Furthermore, contact with ohmic characteristics is made when excavation is not made down as far as the channel, and only the cap is removed, although the contact resistance is high. Therefore, there is no limitation to making the recess down as far as the channel.

Forming the recess portions 142 in this manner, and forming the source electrode and drain electrode as electrodes buried in the recess portions 142, enables an ohmic recess structure to be achieved. Due to the ohmic recess structure, the ohmic contact interfaces, between the source electrode and the drain electrode with the channel layer 114, come into direct contact with the two dimensional electron gas channel 128. As a result, the contact resistance of the ohmic contact interfaces, between the source electrode and the drain electrode with the channel layer 114, can be made smaller, and the electrical characteristics as an HEMT can be raised.

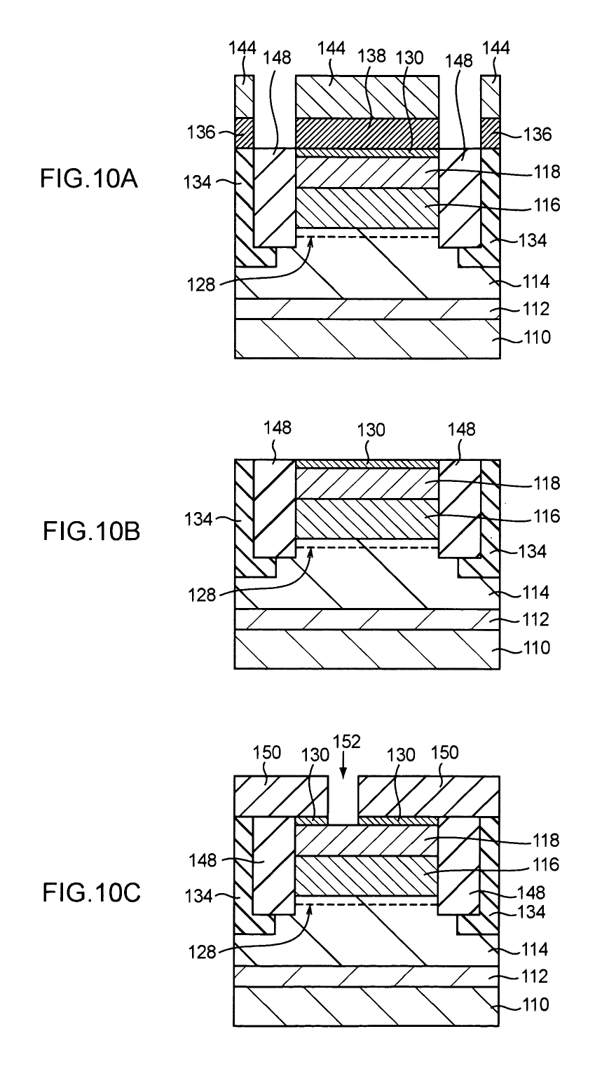

FIG. 10A is a diagram showing an element formed with a titanium thin film or aluminum thin film (referred to as a metal thin film in the following explanation) using, for example, an electron beam vacuum deposition method or the like. A metal thin film 148 is formed to the recess portions 142 and a metal thin film 144 is formed on the photoresist films 136 and 138.

FIG. 10B is a diagram showing an element in which the metal thin film 144 formed on the photoresist films 136 and 138 has been removed by a lift-off method. The metal thin film 144 formed on the photoresist films 136 and 138 is removed together with the removal of the photoresist films 136 and 138, leaving the metal thin film 148 formed on the recess portions 142 remaining. The remaining metal thin film 148 becomes the source electrode 122 and the drain electrode 126 shown in FIG. 5 when the element has been completed.

After removing the photoresist films 136 and 138 and the metal thin film 144 using the lift-off method, annealing is performed in a nitrogen gas atmosphere at 600° C. Due to this annealing, ohmic contact of the metal thin film 148, which will become the source electrode 122 and the drain electrode 126, is formed.

FIG. 10C is a diagram showing an exposed state of the cap layer 118, where a location of a photoresist film 150 and a portion of the protection film 130 have been removed for forming a gate electrode, by coating a photoresist film 150 and application of normal photolithography. The location where the cap layer 118 is exposed is a resist opening 152.

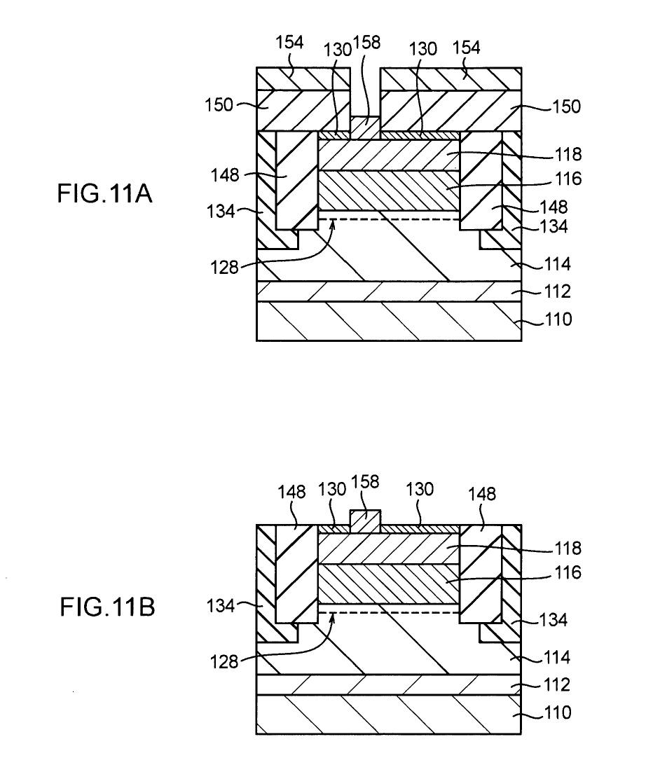

FIG. 11A is a diagram showing a state in which a metal thin film 154 and a metal thin film 158 for forming a gate electrode have been vacuum deposited using, for example, an electron beam vacuum deposition method or the like. The metal thin film formed at the resist opening 152 is shown as the metal thin film 158, and the metal thin film formed on the photoresist film 150 is shown as the metal thin film 154. The metal thin films 154 and 158 are preferably formed using nickel, platinum or gold.

FIG. 11B is a diagram showing an element formed with the metal thin film 158 remaining, and the metal thin film 154 and the photoresist film 150 removed using a lift-off method. The metal thin film 158 (the gate electrode 124 shown in FIG. 5) is formed by a lift-off process. After completing the lift-off process, annealing is performed in a nitrogen atmosphere at 400° C. Due to the annealing, bonding between the metal thin film 158 and the cap layer 118 is raised, achieving better element characteristics.

GaN HEMT of Second Exemplary Embodiment

The basic structure of the GaN HEMT of the second exemplary embodiment of the present invention is similar to that of the GaN HEMT of the first exemplary embodiment explained with reference to FIG. 5, and duplication of explanation is omitted. The point that differs between the GaN HEMT of the first exemplary embodiment and the GaN HEMT of the second exemplary embodiment is the point that the GaN HEMT of the second exemplary embodiment is designed as a HEMT to operate normally off. Therefore, the thickness of the thickness t₁ of the cap layer 118 being set at the minimum as thicker than 11 nm is common in the structure, and in addition, a thickness t₂ of the carrier supply layer 116 shown in FIG. 5 is set within a range such that the value of the threshold voltage Vₜₕ is a positive value.

In an HEMT employed, for example, in amplifiers of RF band, in order to ensure the safety of the device a normally-off HEMT is demanded in which, even when there is damage to the control circuit, there is no shorting between the source and the drain, namely, even though the gate voltage. V_{gs}=0V, a state is secured in which current does not flow between the source and the drain. However, in conventional GaN HEMT's, basically, normally-on HEMT's are easy to manufacture, since the value of the forward voltage V_{f} is about 0.8 to 1.8 V, however the situation is that the range of positive values of the value of the gate voltage V_{gs} cannot be made larger. Therefore, normally-off HEMT's have been designed with the assumption that a large I_{ds-max}, the maximum value of the drain current I_{ds}, cannot be achieved.

As explained with reference to FIG. 5, the carrier supply layer 116 is a non-doped, or Si doped, AlₓGa₁₋ₓN layer, and in the GaN HEMT of the first exemplary embodiment of the present invention the thickness of the carrier supply layer 116 is 10 nm to 30 nm. The Al composition ratio x is from 0.15 to 0.30.

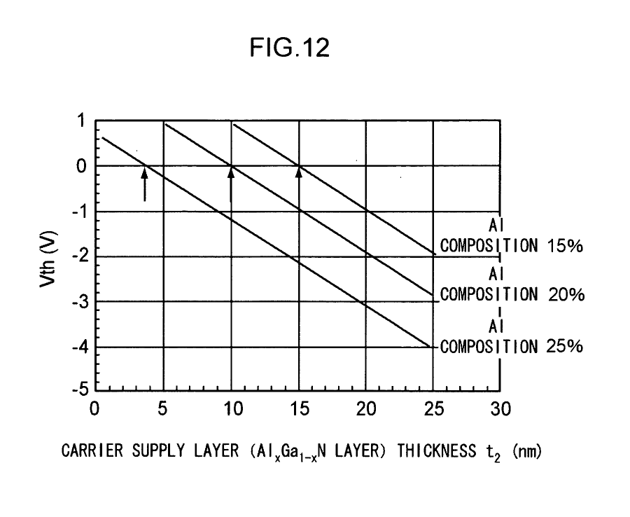

In order to design an HEMT of normally-off operation, namely having a value of 0V or greater for the threshold voltage Vₜₕ, that has basically the same structure as that of the first GaN HEMT, the thickness of the carrier supply layer 116 needs to be controlled. This is explained with reference to FIG. 12.

FIG. 12 shows the relationship of the threshold voltage Vₜₕ against the thickness t₂ of the carrier supply layer 116 when the drain voltage V_{ds} is 10V. FIG. 12 shows an example when the gate length is set at 1.0 μm. The horizontal axis of FIG. 12 shows the thickness of the carrier supply layer 116 (AlₓGa₁₋ₓN layer) on a scale of units of nm, and the vertical axis shows the values of the threshold voltage Vₜₕ on a scale of units of V. FIG. 12 shows cases where the value of the composition ratio x of the AlₓGa₁₋ₓN layer is 0.15, 0.20 and 0.25. Doping has not been performed to the carrier supply layer 116 (AlₓGa₁₋ₓN layer).

Explaining first the case where the value of the composition ratio x of the AlₓGa₁₋ₓN layer is 0.25, in order to achieve normally-off operation (operation with threshold voltage Vₜₕ being in a positive value range), the thickness t₂ of the carrier supply layer 116 needs to be 4 nm or less (see the location of the upward facing arrow on the left hand side in FIG. 12). In a similar manner, when the value of the composition ratio x of the AlₓGa₁₋ₓN layer is 0.20 and 0.15, the thickness t₂ of the carrier supply layer 116 must be 10 nm or less, or 15 nm or less, respectively (see the locations of the upward facing arrows in the middle and on the right hand side in FIG. 12).

As explained above, in order to achieve a value of threshold voltage Vₜₕ that is a positive value, this means that the thickness t₂ of the carrier supply layer 116 must be 15 nm or less, 10 nm or less, or 4 nm or less, when the composition ratio x of the AlₓGa₁₋ₓN layer forming the carrier supply layer 116 is 0.15, 0.20 and 0.25, respectively.

Note that explanation above is related to the thickness t₂ of the carrier supply layer 116 when no doping has been performed to the carrier supply layer 116 (AlₓGa₁₋ₓN layer). When Si is doped to the carrier supply layer 116, it has been confirmed that there is a tendency for the threshold voltage Vₜₕ to be comparatively lower for the same thickness of the carrier supply layer 116. Namely, when the carrier supply layer 116 has been Si doped, the thickness t₂ of the carrier supply layer 116 needs to be comparatively thinner than when no doping is performed. However, when the gate length is made shorter, the thickness of the AlGaN gets thicker. For example, if Lg is 0.1 μm, then for an Al composition of 25%, the thickness of the AlGaN may be 6 nm.

What is claimed is:

1. A gallium nitride high electron mobility transistor comprising:
a channel layer that lets a carrier travel at high velocity;
a carrier supply layer that generates the carrier; and
a cap layer, disposed on the carrier supply layer and functioning to prevent oxidation of the carrier supply layer, to reduce gate leakage current, and to increase voltage withstand to gate voltage, wherein a thickness of the cap layer is set at a minimum as thicker than 11 nm.

2. The gallium nitride high electron mobility transistor of claim 1, wherein a thickness of the carrier supply layer is set in a range enabling the threshold voltage to adopt a positive value.

3. The gallium nitride high electron mobility transistor of claim 1, wherein the cap layer is formed from AlInGaN crystal.

4. The gallium nitride high electron mobility transistor of claim 1, wherein the cap layer is an AlₓIn_{y}Ga_{1-x-y}N crystal layer, doped with Si in a range from 0 to 5×10¹⁸ cm⁻³.

5. The gallium nitride high electron mobility transistor of claim 1, wherein the cap layer is an AlₓIn_{y}Ga_{1-x-y}N crystal layer where the values of x and y, giving composition ratios, are set in a range that satisfies 0≦x<0.1, and 0≦y<0.1.

6. The gallium nitride high electron mobility transistor of claim 1, wherein the carrier supply layer is formed from AlGaN crystal.

7. The gallium nitride high electron mobility transistor of claim 2, wherein the carrier supply layer is formed from AlₓGa₁₋ₓN crystal, with the value of the composition ratio x of the AlₓGa₁₋ₓN set at 0.15, and the thickness of the carrier supply layer set at a value of 15 nm or less.

8. The gallium nitride high electron mobility transistor of claim 2, wherein the carrier supply layer is formed from AlₓGa₁₋ₓN crystal, with the value of the composition ratio x of the AlₓGa₁₋ₓN set at 0.20, and the thickness of the carrier supply layer set at a value of 10 nm or less.

9. The gallium nitride high electron mobility transistor of claim 2, wherein the carrier supply layer is formed from AlₓGa₁₋ₓN crystal, with the value of the composition ratio x of the AlₓGa₁₋ₓN set at 0.25, and the thickness of the carrier supply layer set at a value of 4 nm or less.

10. The gallium nitride high electron mobility transistor of claim 1, wherein the carrier supply layer is formed from AlInGaN crystal.

11. The gallium nitride high electron mobility transistor of claim 1, wherein the carrier supply layer is an AlIn_{z}Ga_{1-z}N crystal layer, doped with Si in a range from 0 to 5×10¹⁸ cm⁻³.

12. The gallium nitride high electron mobility transistor of claim 1, wherein the carrier supply layer is an AlIn_{z}Ga_{1-z}N crystal layer where the value of z giving the composition ratio is set in a range that satisfies 0≦z<0.1.
